(19) United States
(12) Patent Application Publication
(10) Pub. No.: US 2023/0059096 A1
(43) Pub. Date: Feb. 23, 2023

(54) Device comprising a set of Josephson junctions, system comprising such a device and method for using such a device

(71) Applicants: THALES, COURBEVOLE (FR); Centre national de la recherche scientifique, PARIS (FR); UNIVERSITE PARIS-SACLAY, GIF SUR YVETTE (FR)

(72) Inventors: Juan TRASTOY QUINTELA, PALAISEAU CEDEX (FR); Javier E. VILLEGAS, CLAMART (FR); Bruno MARCILHAC, PALAISEAU CEDEX (FR); Pierre SENEOR, PARIS (FR); Yves Eric Jacques LEMAITRE, PALAISEAU CEDEX (FR); David PERCONTE, PALAISEAU CEDEX (FR); Victor ROUCO GOMEZ, PALAISEAU CEDEX (FR); Bruno DLUBAK, MEUDON (FR)

(21) Appl. No.: 17/797,292

(22) PCT Filed: Feb. 4, 2021
(86) PCT No.: PCT/EP2021/052682

§ 371 Date: Aug. 3, 2022

(30) Foreign Application Priority Data
Feb. 5, 2020 (FR) FR2001129

(51) Int. Cl. H01Q 1/36; H01L 39/22; G01R 33/035

(52) U.S. Cl. CPC H01Q 1/364; H01L 39/223; G01R 33/0354

(57) ABSTRACT

The invention relates to a device including a set of superconducting conductors, of junctions and of control elements, each conductor comprising a first portion extending according to a first direction and a set of second portions, the first portions being offset relative to each other according to a second direction, at least three junctions being interposed according to the second direction between each pair of successive first portions, each junction being connected to the first portion of each of the conductors between which the junction is interposed by a second portion of said conductor, each control element being configured to switch the associated junction between a configuration in which the junction forms a Josephson junction and a configuration in which the junction blocks the Cooper pairs.

### TECHNICAL FIELD

The present invention relates to a device including a set of Josephson junctions. The present invention also relates to a system comprising such a device and a method for using such a device.

### BACKGROUND

Josephson junctions including superconducting materials are a component of many electronic devices. Superconductivity is the particularity, for certain materials called superconductors, to present a zero electrical resistance when their temperature is lower than a temperature called critical temperature. Superconductivity is caused by the formation, in the material, of Cooper pairs formed by two electrons.

A Josephson junction is formed by two superconductors separated by a non-superconducting barrier. The barrier is thin enough to allow the Cooper pairs to pass through it, and thus to transit from one superconductor to the other, by tunneling if the barrier layer is electrically insulating, or by classical electronic transport in the opposite case.

Indeed, according to the Josephson effect, the wave function of the Cooper pairs of the first superconductor extends through the barrier, into the second superconductor where it interferes with the wave function of the Cooper pairs of the second superconductor.

The voltage V across the terminals of a Josephson junction, and the intensity I of a current flowing through the junction, are particularly a function of a critical current Ic characteristic of the junction under consideration. This critical current Ic is also a function of the magnetic field component in a plane transverse to the stacking direction of the Josephson junction layers.

When a fixed potential difference is applied across the terminals of a Josephson junction, a sinusoidal Cooper pair electric current is generated and flows through the junction. The frequency of the current is fixed by the voltage V across the terminals of the junction. Such junctions are used in devices called SQUIDs (Superconducting QUantum Interference Device), as well as in transistors.

A SQUID is formed by a superconducting loop including two Josephson junctions arranged in parallel. In a known way, the electric currents flowing in the loop are impacted by any magnetic field passing through the loop, so that the value of the voltage between the two sides of each junction is modified. Thus, by measuring the voltage across the SQUID, it is possible to deduce the value of the local magnetic field, which is why SQUIDs are frequently used in highly sensitive magnetic field detectors.

Arrays of interconnected SQUIDs, called SQIFs (Superconducting Quantum Interference Filters), have, in particular, been proposed for many applications, especially antennas, because of the high sensitivity of SQUIDs to magnetic fields.

In particular, the voltage at the terminals of SQUIDs is a sinusoidal function of the magnetic field value, which makes the analysis of this voltage complex, and requires the use of specific devices. On the contrary, since many SQUIDs are present in a single SQIF, the response of the individual SQUIDs tend to compensate each other above a given magnetic field value, but below this value the variation of the voltage versus the field is monotonic. The voltage analysis is therefore very simple over a range of magnetic fields centered on the zero value.

However, in order to optimize the response of the SQIF over this range, it is necessary to finely control the properties of each of the SQUIDs that compose this SQIF. Furthermore, it is difficult to determine exactly which properties of the SQUIDs allow the response of the SQIF over the range of interest to be optimized.

Therefore, there is a need for a device including a set of Josephson junctions, which is more controllable and more adaptable than the prior art devices.

### SUMMARY

To this end, a device is proposed including a substrate, a set of electrical conductors carried by one face of the substrate, a set of junctions carried by said face of the substrate and a set of control elements, each electrical conductor being made of a superconducting material, each electrical conductor comprising a single first portion extending according to a first direction tangential to the substrate and a set of second portions, the first portions of the electrical conductors being successively offset relative to each other according to a second direction perpendicular to the first direction, at least three junctions being interposed according to the second direction between each pair of successive first portions, each junction being connected to the first portion of each of the conductors between which the junction is interposed by a second portion of said conductor, each control element being associated to a single junction among the set of junctions, and being configured to switch the associated junction between a first configuration in which the junction forms a Josephson junction between the conductors to which the junction is connected, and a second configuration in which the junction prevents passage of Cooper pairs between said conductors.

According to particular embodiments, the device includes one or more of the following features, taken alone or according to any technically possible combination:
the device includes at least ten electrical conductors, with at least ten junctions being interposed between each pair of successive first portions.
each second portion extends according to the second direction.
each junction includes a barrier forming a barrier between the two second portions connected to the junction, at least one of the following properties being verified:
the barrier is made of a ferroelectric material presenting an electrical polarization, the control element being configured to modify a direction of the electrical polarization;
the barrier is made of an electrically insulating material, the junction further including an electrically conductive layer presenting a first face in contact with the two second portions and a second face opposite the first face, the control element including an electrically insulating barrier layer in contact with the second face and a configuration electrode, the barrier layer being interposed between the electrically conductive layer and the configuration electrode, the control element being configured to modify an electrical potential of the configuration electrode, the electrically conductive layer being made in particular of graphene;
the junction includes at least two magnetic layers, each magnetic layer being made of a magnetic material, the junction being configured to have an electric current flowing through the barrier and the two magnetic layers, the control element being configured to modify an orientation of a magnetization of at least one of the magnetic layers.
the device further includes an output electrode, an input electrode, a power supply, and a sensor, the power supply being able to inject an electric current into the input electrode and to set a magnitude of the electric current to a predetermined value, the electric current flowing through each of the conductors from the input electrode to the output electrode, the sensor being able to measure an electric potential difference between the input electrode and the output electrode
each first or second portion is straight.
a distance, measured according to the second direction between the two first portions of a pair of successive conductors, is identical for each pair of successive conductors, and/or a distance, measured according to the first direction between two successive second portions of the same electrical conductor, is identical for each pair of successive second portions.

Also proposed is a system including a control element and a device as previously described, the system being in particular an antenna.

According to one particular embodiment, the control element is configured to:
determining a closed contour on the face of the substrate carrying the conductors and the junctions, the closed contour delimiting a first zone of said face,
controlling a switching of each junction located in the first zone to the corresponding first configuration and a switching of each junction located outside the first zone to the corresponding second configuration
rotating the closed contour through a predetermined angle about an axis perpendicular to the face of the substrate carrying the conductors and the junctions, the closed contour delimiting a second zone after the rotating, and
controlling a switching of each junction located in the second zone to the corresponding first configuration and a switching of each junction located outside the second zone to the corresponding second configuration.

A method is also proposed for using a device including a substrate, a set of electrical conductors carried by the substrate, a set of junctions and a set of control elements, each electrical conductor being made of a superconducting material, each electrical conductor comprising a single first portion extending according to a first direction tangential to the substrate and a set of second portions, the first portions of the electrical conductors being successively offset relative to each other according to a second direction perpendicular to the first direction, at least three junctions being interposed according to the second direction between each pair of successive first portions, each junction being connected to the first portion of each of the conductors between which the junction is interposed by a second portion of said conductor, the method including a step of switching at least one junction between a first configuration in which the junction forms a Josephson junction between the conductors to which the junction is connected and a second configuration in which the junction prevents the passage of Cooper pairs between said conductors.

According to a particular embodiment, at the end of the switching step, each junction included in a first zone of the face of the substrate carrying the conductors and the junctions is, in the first configuration, the first zone being delimited by a closed contour on said face, each junction arranged outside the first zone being in the second configuration, the method further including the following steps:
rotating the closed contour through a predetermined angle about an axis perpendicular to the face of the substrate carrying the conductors and the junctions, the closed contour delimiting a second zone on said face after the rotating step, and
switching of each junction included in the second zone to the corresponding first configuration and switching of each junction located outside the second zone to the corresponding second configuration.

### BRIEF DESCRIPTION OF THE DRAWINGS

Features and advantages of the invention will become apparent from the following description, given only as a non-limiting example, and made with reference to the appended drawings, in which:

FIG. 1 is a schematic representation of a system including a device comprising a set of Josephson junctions,

FIG. 2 is a partial schematic representation of a device comprising a set of Josephson junctions of FIG. 1,

FIG. 3 is a zoom on portion III of FIG. 2,

FIG. 4 is a schematic representation of the device of FIG. 2, in which certain Josephson junctions have been deactivated,

FIG. 5 is a flowchart of the steps of a method for using a system of FIG. 1,

FIG. 6 is a schematic representation of a device comprising a set of Josephson junctions according to the invention, in a state corresponding to one of the steps of the method of FIG. 5,

FIG. 7 is a schematic representation of another example of a Josephson junction of FIG. 2,

FIG. 8 is a schematic representation of a third example of a Josephson junction of FIG. 2, and

FIG. 9 is a schematic representation of a fourth example of a Josephson junction of FIG. 2.

### DETAILED DESCRIPTION OF EMBODIMENTS

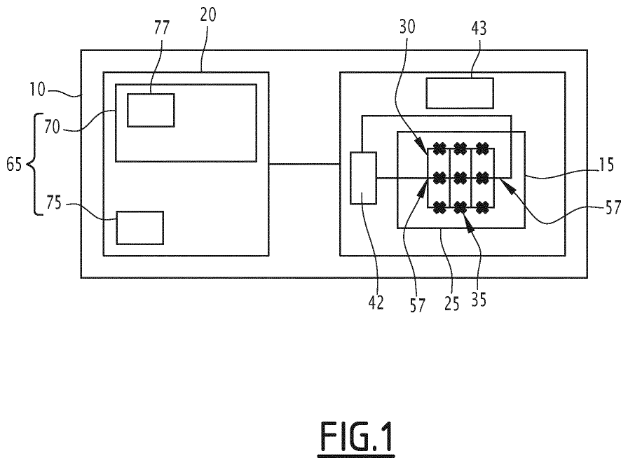

A first example of the system 10 is shown schematically in FIG. 1.

The system 10 is, for example, a radio frequency transmission system such as an antenna.

In particular, the system 10 is suitable for transmitting and/or receiving, especially for receiving, electromagnetic waves presenting a frequency between zero and 4 Terahertz (THz).

Alternatively, the system 10 is an amplifier, in particular a low noise amplifier, a magnetic field sensor, an analog-to-digital converter, or a filter.

The system 10 includes a device 15 and a control module 20.

The device 15 includes a substrate 25, a set of electrical conductors 30A, 30B, a set of junctions 35, a set of control elements 40, a power supply 42 and a sensor 43.

As will become apparent later, the electrical conductors 30A, 30B and junctions 35 are suitable for forming a SQIF including a set of interconnected SQUIDs, in particular a two-dimensional array of SQUIDs. In particular, each SQUID is formed by portions of conductors 30A, 30B forming a superconducting loop and by two junctions 35 separating the loop into two portions connected to each other by the junctions 35. Thus, the two junctions 35 are connected in parallel between the two conductors 30A, 30B.

The substrate 25 is provided to support each electrical conductor 30A, 30B, each junction 35 and each control element 40.

The substrate 25 is made of an electrically insulating material such as sapphire or magnesium oxide MgO.

The substrate 25 presents a support face 45. The support face 45 is flat.

In particular, a normal direction Z, perpendicular to the support face 45, is defined for the substrate 25. A first direction X and a second direction Y are also defined. The first direction X and the second direction Y are perpendicular to each other, and perpendicular to the normal direction Z.

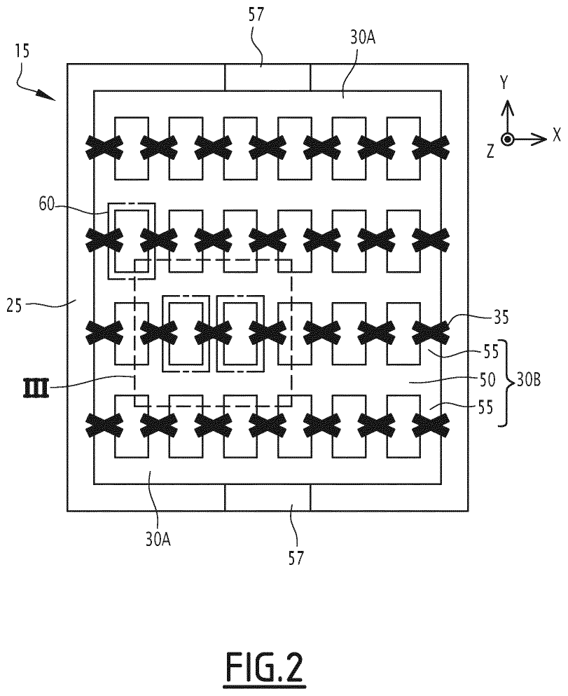

The number of conductors 30A, 30B is greater than or equal to two. According to the example shown schematically in FIG. 2, the device 15 includes five conductors 30A, 30B. However, it should be noted that the number of conductors 30A, 30B may vary, in particular to be greater than or equal to 10, in particular to be greater than or equal to 100.

The set of conductors 30A, 30B includes two end conductors 30A and at least one conductor 30B, in particular a plurality of conductors 30B, interposed between the two end conductors 30A according to the second direction Y. In particular, the conductors 30B are successively offset relative to each other according to the second direction Y.

Two conductors 30A, 30B are said to be “successive” or “adjacent” if no other conductor 30A, 30B is interposed between the two conductors considered according to the second direction Y.

The conductors 30A, 30B are electrically connected in series. In particular, the set of conductors 30A, 30B is configured so that an electric current passes successively through one of the end conductors 30A, each conductor 30B and then the other end conductor 30A.

Each conductor 30A, 30B includes a single first portion 50 and a set of second portions s 55.

Each end conductor 30A is electrically connected to a first electrode 57. In particular, the conductors 30A, 30B are interposed according to the second direction Y between the two first electrodes 57.

Each conductor 30A, 30B is made of a first material M1.

The first material M1 is a superconducting material.

The first material M1 presents a first resistivity R1, which is temperature dependent.

The resistivity of a material is defined as the electrical resistance of a section of material 1 meter (m) long and 1 m² in cross-section. Resistivity is, generally, expressed in ohm-meters (Ω-m). The electrical resistance measured between two contacts is defined as the ratio between the voltage measured across the terminals of the two contacts and the electrical current flowing in a leg of the circuit through the two terminals.

It is understood by the term “superconducting material” that the first material M1 presents a first critical temperature Tc1. When the first material M1 is at a temperature less than or equal to the first critical temperature Tc1, the first resistivity R1 is zero.

In particular, the first critical temperature Tc1 is less than or equal to a set temperature Tc at which the device 15 is intended to be used.

The charge carrier concentration is defined as the sum of the electrical charges of each charge carrier per unit volume of first material M1.

The first material M1 is, for example, a material of the cuprate family. Cuprates are chemical compounds containing copper cations. Many compounds in the cuprate family exhibit the properties described above.

For example, the first material M1 is a mixed oxide of barium, copper, and yttrium. Mixed oxides of barium, copper, and yttrium, also noted as YBCO are crystalline chemical compounds frequently presenting the chemical formula YBa₂Cu₃O_{7-δ}, where δ is a real number greater than or equal to zero. Preferably, δ is between 0 and 0.6.

The first material M1 is, for example, NdBaCuO or LaBaCuO.

It should be noted that other types of first materials M1 are conceivable, for example Nb or NbSn.

The first portion 50 of each conductor 30A, 30B is carried by the support face 45.

The first portion 50 extends, for example, according to a direction tangential to the substrate 25, that is, in a direction perpendicular to the normal direction Z. According to the example shown in FIG. 2, the first portion 50 of each conductor 30A, 30B extends according to the first direction X.

Each first portion 50 is, for example, straight. Alternatively, the first portion presents a curved shape in a plane perpendicular to the normal direction Z, for example a sinusoidal shape about a portion of a line parallel to the first direction X.

Each first portion 50 is, for example, a portion of a layer of the first material M1 carried by the support face 45.

According to one embodiment, each first portion 50 presents a thickness, measured according to the normal direction Z, of between 30 nanometers (nm) and 200 nm.

A width of the first portion 50, measured for example according to the second direction Y, is between 100 nm and 2 micrometers (μm).

The first portions 50 of the conductors 30A, 30B are successively offset according to the second direction Y relative to each other. For example, each first portion 50 extends according to a separate line, the separate lines being parallel to each other.

According to the embodiment shown in FIG. 2, the first portions 50 of the conductors 30A, 30B are not offset relative to each other according to the first direction X. However, embodiments in which at least two successive first portions 50 are offset relative to each other according to the first direction X are also conceivable.

A distance between the separate lines of two successive first portions 50 is, for example, between 300 nm and 10 μm. According to one embodiment, this distance is uniform. In other words, this distance is equal for each pair of two first portions 50 belonging to two successive conductors 30.

Each first portion 50 is distinct from the other first portions 50, in particular each first portion 50 is distant from the other first portions 50. A distance between two successive first portions 50 is, for example, between 300 nm and 10 μm.

According to one embodiment, the first portions 50 of each pair of first portions 50 selected from the set of first portions 50 of the conductors 30A, 30B are superimposable on each other by a translation according to the second direction Y.

The set of second portions 55 of each conductor 30A, 30B comprises at least three second portions 55, in particular at least six second portions. In the embodiment shown in FIG. 2, each end conductor 30A includes seven second portions 55, and each conductor 30B interposed between the end conductors 30A comprises 14 second portions.

It should be noted that the number of second portions 55 of each conductor 30A, 30B is likely to vary, for example to be greater than or equal to 10, particularly greater than or equal to 100.

Each second portion 55 extends, for example, according to a direction tangential to the substrate 25. According to the example shown in FIG. 2, each second portion 55 extends according to the second direction Y. However, embodiments in which the second portions 55 extend according to a direction different from the second direction Y are also conceivable.

Each second portion 55 is, for example, straight. Alternatively, the first portion presents a curved shape in a plane perpendicular to the normal direction Z, for example a sinusoidal shape about a portion of a line parallel to the second direction Y.

Each second portion 55 is, for example, a portion of a layer of the first material M1 carried by the support face 45.

According to one embodiment, each second portion 55 presents a thickness, measured according to the normal direction Z, of between 30 nm and 200 nm.

A width of each second portion 55, measured for example along the first direction X, is between 100 nm and 2 μm.

Each second portion 55 extends, for example according to the second direction Y, from the first portion 50. In particular, each second portion 55 connects the first portion 50 to a junction 35 interposed between the conductor 30A, 30B under consideration and a conductor 30A, 30B adjacent to this conductor 30A, 30B.

The set of second portions 55 includes, for each conductor 30B, a first subset and a second subset.

The first portion 50 is interposed according to the second direction Y between the two subsets of the second portions 55.

In particular, each conductor 30B being interposed between two conductors 30A, 30B adjacent to the conductor 30B under consideration, each second portion 55 of the first subset extending from the first portion 50 of the conductor 30B under consideration towards one of the two adjacent conductors 30A, 30B, each second portion 55 of the second subset extending towards the other of the two adjacent conductors 30A, 30B of the conductor 30B under consideration.

According to one embodiment, each subset of one conductor 30B includes a number of second portions 55 equal to the number of second portions 55 of the other subset. In particular, each second portion 55 of one subset is aligned according to the direction Y with a second portion 55 of the other subset.

Each second portion 55 of an end conductor 30A extends according to the second direction Y towards the single conductor 30B adjacent to the end conductor 30A under consideration. Thus, each end conductor 30A includes a single subset of second portions 55.

The second portions 55 of a same subset are successively offset according to the first direction X relative to each other. For example, each second portion 55 extends according to a separate line, with the separate lines being parallel to each other.

A distance between the separate lines of two successive second portions 55 of a same subset is, for example, between 300 nm and 10 μm. According to one embodiment, this distance is uniform. In other words, this distance is equal for each pair of successive second portions 55.

In particular, “two successive second portions 55” is understood to mean two second portions 55 between which no other second portion 55 is interposed.

Each second portion 55 is distinct from the other second portions 55, in particular each second portion 55 is distant from the other second portions 55. A distance between two successive second portions 55 is, for example, between 300 nm and 10 μm.

Thus, two successive second portions 55 of the same conductor 30A, 30B, connected to two junctions 35, form a superconducting loop with the two second portions 55 connected to the same junctions 35 of an adjacent conductor 30A, 30B.

This loop extends along a closed separate line 60. The closed separate line 60 extends successively along a first junction 35, of a first second portion 55 of a first conductor 30A, 30B, of a part of the first portion 50 of this conductor 30A, 30B, of another second portion 55 of this conductor, of a second junction 35, of a third second portion 55 of a second conductor 30A, 30B, of a part of the first portion 50 of this conductor 30A, 30B and a fourth second portion 55 of this conductor 30A, 30B to return to the first junction 35.

In particular, each pair of successive second portions 55 of the same conductor 30A, 30B is part of a superconducting loop including these two second portions 55. Thus, each second portion 55 forms part of one or two superconducting loops with the two adjacent second portion(s) 55.

In particular, each second portion 55 presents a length equal to the length of each other second portion 55 that is interposed between the same conductors 30A, 30B as the second portion 55 under consideration. For example, a length of each second portion 55 is identical to the length of each other second portion 55.

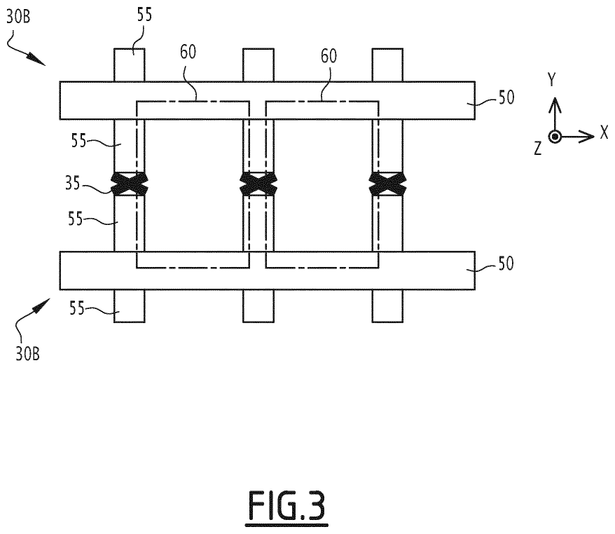

A detail of FIG. 2 is shown in FIG. 3, where two conductors 30B are partially distinguished, each connected by second portions 55 to junctions 35 interposed between the two conductors 30B under consideration. Because of the partial representation of the two conductors 30B, only three junctions 35 and, for each conductor 30B, six second portions 55, are visible. Among these six second portions 55, three connect the conductor 30B under consideration to the three junctions 35, and three second portions 55, partially visible, away from the junctions 35.

Thus, each group of two successive junctions 55 is part of a superconducting loop including two junctions 35 and extending along a closed separate line 60.

According to one embodiment, the second portions 55 of each subset are superimposable on each other by translation according to the first direction X.

The set of junctions 35 comprises, for each pair of successive conductors 30A, 30B, at least three junctions 35 interposed between the conductors 30A, 30B under consideration according to the second direction Y. In particular, each junction 35 is interposed between the first portions 50 of the conductors 30A, 30B under consideration.

According to the example shown in FIG. 2, the set of junctions 35 comprises, for each pair of successive conductors 30A, 30B, seven junctions 35 interposed between the conductors 30A, 30B under consideration according to the second direction Y.

It should be noted that the number of junctions 35 interposed between each pair of successive conductors 30A, 30B is likely to vary, in particular to be greater than or equal to 10, in particular to be greater than or equal to 100.

More precisely, each junction 35 is connected to the first portion 50 of each of the successive conductors 30A, 30B between which is interposed a second portion 55 of said conductor 30A, 30B. In particular, the junction 35 is electrically connected to the two corresponding second portions 55.

In particular, each junction 35 includes a barrier 63 interposed between the two second portions 55 connected to the junction 35. In particular, the barrier 63 is in contact with the two second portions 55 which are connected to the junction 35. The barrier 63 then forms the third portion.

The barrier 63 will be described in more detail below.

Each junction 35 is suitable for switching between a first configuration and a second configuration.

In FIG. 2, each junction 35 is in its first configuration, shown symbolically by a cross.

When it is in the first configuration, each junction 35 forms a Josephson junction between the two conductors 30A, 30B, in particular between the two second portions 55 to which the junction 35 is connected. In particular, when the junction 35 forms a Josephson junction between the two second portions 55, the junction 35 is suitable for allowing the transfer of Cooper pairs between these two second portions 55.

For example, junction 35 is able to allow the transfer of Cooper pairs between the two second portions 55 by electrical conduction. Alternatively, the junction 35 is able to allow the transfer of Cooper pairs between the two second portions 55 by tunneling effect.

In particular, each pair of successive junctions 35 interposed between two same conductors 30A, 30B, in other words, each pair of junctions 35 between which no other junction 35 is interposed according to the first direction X, forms a SQUID with the second portions 55 to which they are connected and with the parts of the first portions 50 interposed between these second portions 55. Notably, each superconducting loop extending according to a closed separate line 60 forms a SQUID with the two junctions 35 that it includes.

When it is in the second configuration, junction 35 prevents the passage of Cooper pairs between the two conductors 30A, 30B to which it is connected. In particular, the junction 35 prevents the passage of Cooper pairs between these two conductors 30A, 30B, especially between the two second portions 55 connected to the junction 35. The junction 35 thus does not form a Josephson junction.

For example, when junction 35 is in its second configuration, junction 35 is electrically conductive but not superconducting. Thus, the junction allows an electrical current to flow between the two conductors 30A, 30B to which it is connected, but does not allow Cooper pairs to flow.

Alternatively, when a junction 35 prevents the passage of Cooper pairs between the two conductors 30A, 30B to which it is connected, this junction 35 prevents the passage of an electrical current between the two conductors 30A, 30B. The junction 35 is then electrically insulating.

Each control element 40 is associated to a corresponding junction 35.

Each control element 40 is configured to switch the corresponding junction 35 between the first configuration and the second configuration.

For example, each control element 40 is configured to change a value of the critical current of the associated junction 35 between a first value and a second value. When the critical current presents the first value, the junction 35 forms a Josephson junction when the junction 35 is at the set temperature Tc. When the critical current presents the second value, the junction 35 does not form a Josephson junction when the junction 35 is at the set temperature Tc.

Alternatively, each control element 40 configured to vary the critical temperature of a portion of the junction 35 between a first value strictly lower than the set temperature Tc and a second value strictly greater than the set temperature Tc.

The power supply 42 is configured to circulate an electric current between the two first electrodes 57. The electric current is, for example, a direct current.

In particular, the power supply 42 is configured to set a value of a first parameter of the electric current, in particular the current, to a predetermined value. Alternatively, the parameter is a voltage.

The electric current successively flows through a first electrode 57, the associated end conductor 30A, each conductor 30B, the other end conductor 30A, and then the other first electrode 57.

The sensor 43 is able to measure a value of a second parameter of the electric current, the second parameter being distinct from the first parameter. The second parameter is, for example, an electrical voltage between the two first electrodes 57.

The control module 20 is configured to control each control element 40. The control module 20 is further configured to maintain a temperature of the control module 20 at the set temperature Tc.

The control module 20 is further configured to implement a method for using the device 15.

The control module 20 includes a data processing unit 65 comprising a memory 70 and a processor 75. The memory 70 comprises a set of software instructions 77, stored in the memory 70 and suitable for implementing the method of use when executed by the processor 75.

Alternatively, the data processing unit 65 may be realized in the form of programmable logic components or dedicated integrated circuits.

The method comprises at least a first switching step 200. The first switching step 200 comprises the switching, by the associated control element (s) 40, of at least one junction 35 between its first configuration and its second configuration.

For example, the first switching step 200 comprises switching at least one junction 35 from its first configuration to its second configuration. In particular, the control module 20 commands the switching, by the corresponding control element (s) 40 of at least one junction 35 from its first configuration to its second configuration.

Each junction 35 in its second configuration prevents the passage of Cooper pairs between the second portions 55 connected to the junction 35. Thus, junction 35 does not form a Josephson junction between these second portions 55.

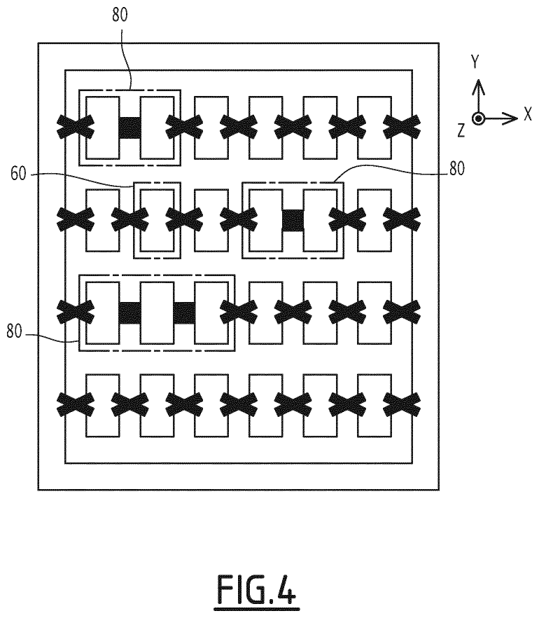

An example of the device 15 at the end of the first configuration step 35 is shown in FIG. 4, considering that the device 15 was, prior to the first switching step 200, in the configuration shown in FIG. 2 and in which each junction 35 formed a Josephson junction.

When each junction 35 forms a Josephson junction, each pair of successive junctions 35 belongs to a SQUID comprising these two junctions 35, the four second portions 55 connected thereto and the parts of the first portions 50 included between these second portions 55. Each SQUID thus corresponds to a superconducting loop extending along a closed separate line 60 that includes only two junctions 35. In particular, the separate line 60 does not surround any other junctions 35.

Each SQUID thus presents an area equal to the area delimited by two successive first portions 50 according to the second direction Y and by two successive second portions 55 according to the first direction X.

To simplify understanding, only the separate lines 60 corresponding to three SQUIDs are shown in FIG. 2, but it should be noted that each pair of successive junctions 35 forms a SQUID extending according to a separate line 60.

It is considered, by way of example, that during the first switching step 200, four of the junctions 35 switch to their second configuration. These junctions 35 are shown symbolically as squares in order to distinguish them from the other junctions 35 which are in their respective first configurations.

Each of the junctions 35 in their second configuration does not allow the passage of Cooper pairs and therefore does not participate in the formation of a SQUID. However, junctions 35 that are in their respective first configurations and that surround, according to the first direction X a group of one or more successive junctions 35 prevent the passage of Cooper pairs forming a SQUID extending along a closed separate line 80 surrounding the group of junctions 35 in question.

Thus, in FIG. 4, where one group of two successive junctions 35 and two groups of a single junction 35 have been switched into the associated second configurations, three SQUIDs associated to separate lines 80 are formed. The remaining SQUIDs corresponding to junctions 35 that have not been switched are not changed.

Each SQUID associated to a separate line 80 presents a strictly larger area than the SQUIDs associated to separate line 60.

According to an optional addition, the junctions 35 that should be in their first configuration and the junctions 35 that should be in their second configuration after the first switching step 200 are selected by a deep learning method.

Deep learning methods are machine learning methods in which an apparatus, in particular the control module 20, models data with a high level of data abstraction.

Such a deep learning method implements, for example, an optimization algorithm in which a cost function for the device 15 is defined, which the control module 20 attempts to minimize relative to the intended application for the system 10.

Deep learning methods comprise, for example, the implementation of a neural network. A neural network is typically composed of a succession of layers, each of which takes its inputs from the outputs of the previous layer. Each layer is composed of a plurality of neurons, taking their inputs from the neurons of the previous layer. Each synapse between neurons is associated to a synaptic weight, so that the inputs received by a neuron are multiplied by this weight, and then summed by the said neuron. The neural network is optimized by adjusting the different synaptic weights during the learning phase.

Since the electrical behavior of the SQUIDs is a function of the area of each SQUID in the presence of a magnetic field, it is possible to modify the device 15 by turning on or off (in other words, switching to the first or second configuration) the junctions 35 after the device 15 has been manufactured. Thus, the device 15 is more controllable and adaptable than the devices of the prior art.

In addition, the device 15 is less sensitive to possible inaccuracies in the manufacture of the loops forming the SQUIDs (inaccuracies arising, in particular, from inaccuracies in the manufacture of the conductors 30A, 30B or the junctions 35), since the effects of such inaccuracies are likely to be compensated for by the selection of a suitable set of junctions 35 to be switched into their second configuration.

When the device 15 includes at least ten electrical conductors 30A, 30B, with at least ten junctions 35 interposed between each pair of successive conductors 30A, 30B, the device 15 is particularly adjustable.

When each second portion 55 extends according to the second direction, the design of the device 15, and in particular the design of the mask(s) used to photolithographically manufacture the device 15, is simplified, as well as when each first and second portion 50, 55 is straight. Manufacturing is further simplified when the distance between each pair of successive second portions 55 is identical for all pairs of second portions 55, as well as when the distance between each pair of successive first portions 50 is identical for all pairs of successive first portions 50.

When the power supply 42 is configured to impose an intensity of the electric current flowing between the two end conductors 30A, and the sensor 43 is suitable for measuring an electric voltage between these two end conductors 30A, the device 15 is advantageously usable as an electromagnetic wave receiving element in an antenna, since the voltage depends on the magnetic field perceived by each SQUID.

According to one embodiment of the method of use, the method further comprises a determination step 210, a rotating step 220 and a second switching step 230. In particular, the determination step 210 is followed successively by the first switching step 200, the rotating step 220 and the second switching step 230.

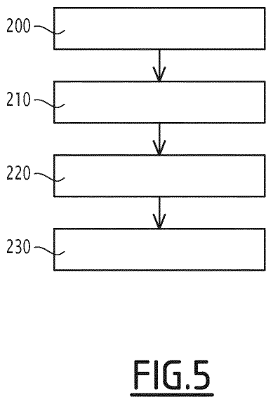

A flowchart of steps 200 to 230 is shown in FIG. 5.

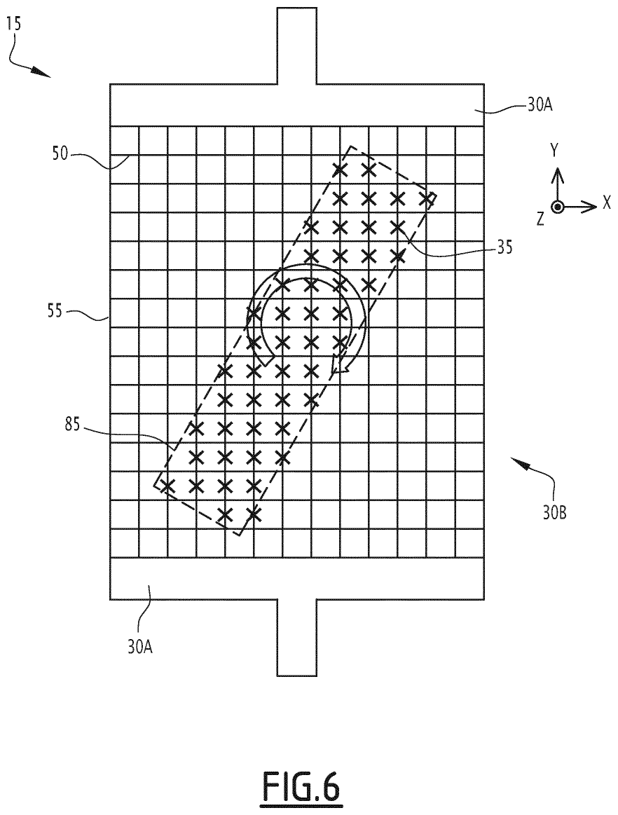

This embodiment is particularly suitable for implementation by large devices 15. For example, the operation of this embodiment is shown in FIG. 6 in the case of a device 15 including 16 conductors 30A, 30B, each including 14 (case of conductors 30A) or 28 (case of conductors 30B) second portions 55. It should be noted that the number of conductors 30A, 30B and second portions 55 may vary.

In FIG. 6, in order not to overload the figure, the first and second portions 50 and 55 are shown by thin lines, except for the first portions 55 of the end conductors 30A, which are shown by thick lines.

In the determination step 210, the control module 20 determines a closed contour 85 on the support face 45. The closed contour 85 delimits a first zone on this face 45.

The closed contour 85 presents a maximum dimension and a minimum dimension measured according to directions perpendicular to each other, the maximum dimension being strictly greater than the minimum dimension. The closed contour 85 is, thus, a non-circular contour.

A ratio between the maximum dimension and the minimum dimension is, for example, greater than or equal to 3, in particular greater than or equal to 5, in particular greater than or equal to 10.

The closed contour 85 is, for example, rectangular, as shown in FIG. 6. In this case, the maximum dimension is the length of the largest side of the rectangle, and the minimum dimension is the length of the smallest side of the rectangle.

Alternatively, the closed contour 85 is elliptical, in which case the maximum dimension is the major axis of the ellipse, and the minimum dimension is the minor axis of the ellipse. However, other shapes are also possible.

The closed contour 85 presents an area between 10 μm² and 10 square centimeters (cm²).

In particular, the closed contour 85 surrounds a group of junctions 35 comprising at least 50 separate junctions 35.

In the first switching step 200, the control module 20 controls the switching of each junction 35 included in the first zone to its first configuration and controls the switching of each junction 35 located outside the first zone to its second configuration. In FIG. 6, each junction 35 in its first configuration is shown with a cross, while junctions 35 that are in their second configurations are not shown.

During the rotating step 220, the control module 20 rotates the closed contour 85 about an axis parallel to the normal direction Z. This is shown symbolically in FIG. 6 by an arrow.

For example, the control module 20 rotates the closed contour 85 through a predetermined angle during the rotating step 220.

The closed contour 85 delimits a second zone distinct from the first zone after the rotating step 220.

During the second switching step 230, the control module 20 controls the switching of each junction 35 included in the second zone to its first configuration and controls the switching of each junction 35 located outside the second zone to its second configuration.

In particular, steps 200 to 230 are repeated successively in the order detailed above so as to rotate the closed contour 85 by 360 degrees)(° or more, according to the number of iterations of steps 200 to 230. In particular, steps 200 to 230 are repeated so as to achieve periodic rotation of the closed contour with a rotational speed between 100 degrees per second and 10,000 degrees per second. However, the rotational speed is likely to vary.

Flipping a junction 35 from the first to the second configuration does not significantly change the electrical resistance of the junction, so that the electrical voltage between the end conductors 30A is not changed by the rotation of the contour 85. However, the electrical voltage between these two conductors 30A depends on the homogeneity of the magnetic field perceived by the different SQUIDs formed by the junctions 35 that are in their first configurations. In particular, the difference (in absolute value) between the value of the electric voltage in the presence of a magnetic field, for example the magnetic field of a radio-frequency electromagnetic wave, and the value of the electric voltage in the absence of this magnetic field is all the greater as the magnetic field is homogeneous over the different SQUIDs.

Thus, when the closed contour 85 is such that the maximum dimension is measured according to a direction perpendicular to the direction of propagation of the electromagnetic wave, the variation of the voltage caused by the electromagnetic wave is maximum, whereas it is minimum when the minimum dimension is measured according to a direction perpendicular to the direction of propagation. Thus, when the system 10 is an antenna, the system 10 is suitable for determining the propagation direction of an electromagnetic wave received by the device 15.

Furthermore, the rotational speed of the closed contour 85 is likely to be much higher than the rotational speeds of prior art antennas in which the antenna, possibly including one or more SQUIDs, is mechanically rotated.

Examples of junctions 35 presenting a first configuration and a second configuration are given below. Each of these example junctions 35 is suitable for use in a device 15 as previously defined.

Examples of a control element 40 suitable for switching the various example junctions 35 are also described.

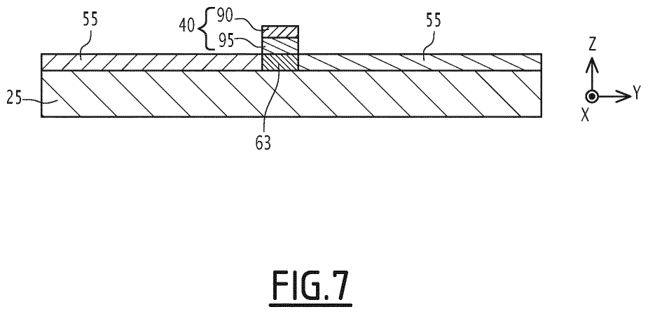

A first example of the junction 35 is shown in FIG. 7.

The barrier 63 is made of a second material, which is for example superconducting. For example, the barrier 63 is made of the first material M1.

The barrier 63 is electrically connected to the two second portions 55 that connect the junction 35 to the first portions 50 of the conductors 30A, 30B between which the junction 35 is interposed.

The control element 40 comprises a ferroelectric layer 90 and a second electrode 95.

The ferroelectric layer 90 is in contact with the barrier 63. For example, the ferroelectric layer 90 and the barrier 63 are stacked on top of each other according to a stacking direction that is, in particular, the normal direction Z, as shown in FIG. 7. However, the stacking direction may vary.

The ferroelectric layer 90 is made of a third material M3.

An electrical polarization PE is defined for the third material M3. This means that the third material M3 presents a plurality of electric dipoles each generating an electric moment, and the electric polarization PE is defined as the average, per unit volume, of the electric moments. The electrical polarization PE is therefore a vector quantity.

The third material M3 is a ferroelectric material.

This means that the PE polarization is non-zero in the absence of an external electric field. In other words, the barycenter of the positive charges and the barycenter of the negative charges in the barrier 63 are not conflated, even in the absence of an external electric field.

The PE polarization is mobile between a first orientation O1 and a second orientation O2.

When the PE polarization is in the first orientation O1, the PE polarization presents at least one component parallel to the stacking direction. This means that the first orientation O1 is not perpendicular to the stacking direction.

When the PE polarization is in the second orientation O2, the PE polarization presents at least one component parallel to the stacking direction. The component is in the opposite direction to the direction of the first orientation O1.

Preferably, the first orientation O1 is parallel to the stacking direction.

For example, when the PE polarization is in the first orientation O1, the PE polarization is directed toward the barrier 63.

In particular, the ferroelectric layer 90 is interposed between the barrier 63 and the second electrode 95. For example, the ferroelectric layer 90 is delimited according to the stacking direction by the barrier 63 and the second electrode 95. Alternatively, one or more additional layers may be interposed between the ferroelectric layer 90 and one or other of the barrier 63 and the second electrode 95.

In particular, the control element 40 is configured to control the direction of the PE polarization of the ferroelectric layer 90.

For example, the control element 40 is able to control the direction of the PE polarization via a voltage pulse between the second electrode 95 and one of the first electrodes 57. This means that the control element 40 is configured to impose, for a predetermined time duration, a potential difference V2 between the two faces of the ferroelectric layer 90 that delimits this layer 90 according to the stacking direction.

For example, the control element 40 is configured to generate an electric current between a first electrode 57 and the second electrode 95.

The voltage pulse changes the orientation of the electrical polarization PE of the ferroelectric layer 90.

For example, when the sign of the potential difference V2 is positive, the polarization PE is rotated from the first orientation O1 to the second orientation O2. On the contrary, when the sign of the potential difference V2 is negative, the polarization PE is rotated from the second orientation O2 to the first orientation O1.

The polarization PE causes electrical charge to accumulate in the barrier 63 when the polarization PE is in the first orientation O1.

The charge accumulation reduces the critical temperature of the barrier 63 from a first value T1 strictly higher than the set temperature Tc to a second value T2 strictly lower than the set temperature Tc.

The second value T2 being strictly lower than the set temperature Tc, the barrier 63 is therefore not superconducting when the polarization PE is in the second orientation O2.

On the contrary, when the polarization PE is in the first orientation O2, the polarization PE does not cause charge accumulation in the barrier 63. The barrier 63 is therefore superconducting.

Thus, the control element 40 is able to modify the characteristics of the barrier 63 according to whether the barrier 63 is superconducting or not at the set temperature Tc.

In particular, the critical temperature and/or critical current values of the junction 35 are different according to whether the barrier 63 is superconducting or not. In particular, the critical temperature and/or the critical current each present a strictly lower value when the barrier 63 is not superconducting than when the barrier 63 is superconducting. Thus, the junction 35 forms a Josephson junction when the barrier 63 is superconducting and prevents the passage of Cooper pairs between the two portions 55 when the barrier 63 is not superconducting.

This first example of junction 35 does not require the application of a voltage to remain in either configuration, and allows for rapid switching.

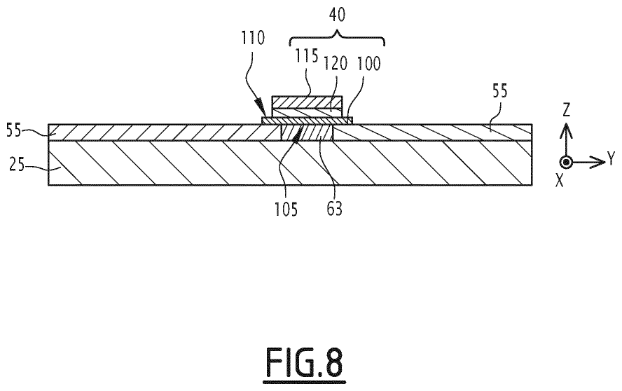

A second example of junction 35 and an associated control element 40 is shown in FIG. 8.

The junction 35 comprises, in addition to the barrier 63, an electrically conductive layer 100.

The barrier 63 is made of a non-superconducting material. For example, the barrier 63 is made of an electrically insulating material. According to one embodiment, the barrier 63 is made of a material obtained by irradiating the first material M1 with an ion beam. For example, such a material is obtained by irradiating YBCO with oxygen or helium ions.

The barrier 63 presents a width, measured according to the direction Y, of between 500 nm and 5 μm. In particular, the barrier 63 prevents the passage of Cooper pairs between the second portions 55. In particular, the barrier 63 is in contact with the two second portions 55 to which the junction 35 is connected.

The electrically conductive layer 100 is perpendicular to a stacking direction, which is, for example, the normal direction Z, although other directions are conceivable.

The electrically conductive layer 100 is, for example, made of graphene. However, other electrically conductive materials are also conceivable, including materials presenting Dirac cones in their band structure.

The electrically conductive layer 100 presents a thickness of less than or equal to 5 nm. In particular, the electrically conductive layer 100 is a monoatomic layer.

The electrically conductive layer 100 presents a first face 105 and a second face 110.

The first face 105 is in contact with the barrier 63. In particular, the first face 105 is in contact jointly with the barrier 63 and with the two portions 55, in particular with the ends of the two portions 55.

The first face 105 is flat, in particular perpendicular to the stacking direction.

The second face 110 is opposite the first face 105. In particular, the layer 100 is delimited by the first face 105 and the second face 110 according to the stacking direction.

The control element 40 includes a configuration electrode 115 and a barrier layer 120.

The configuration electrode 115 is made of an electrically conductive material, such as gold.

The barrier layer 120 is interposed between the configuration electrode 115 and the electrically conductive layer 100. In particular, the barrier layer 120 is in contact with the second side 110.

The barrier layer 120 is interposed between the configuration electrode 115 and the layer 100. The barrier layer 120 is made of an electrically insulating material, such as aluminum oxide.

The control element 40 is configured to change an electrical potential of the configuration electrode 120. In particular, the control element 40 is configured to change an electrical potential of the configuration electrode 120 between a third value and a fourth value.

Switching the electrical potential of the electrode 120 between the third and fourth values moves the Fermi level of the electrically conductive layer 100 between a fifth value and a sixth value.

When the Fermi level presents the fifth value, passage of Cooper pairs through the electrically conductive layer 100 is possible, whereas such passage is not permitted when the Fermi level presents the sixth value.

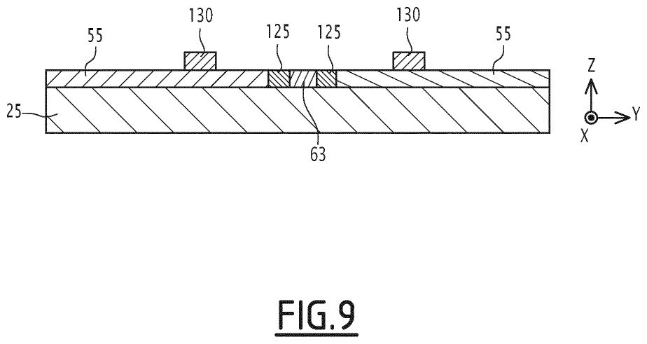

A third example of junction 35 is shown in FIG. 9, with a portion of an associated control element 40.

The junction 35 includes, in addition to the barrier 63, at least two magnetic layers 125. The junction 35 is able to allow an electric current to flow from one of the corresponding second portions 55 to the other second portion 55, the electric current flowing through the barrier 63 and the two magnetic layers 125.

The magnetic layers 125 surround, for example, the barrier 63 according to the second direction Y. In particular, each magnetic layer 125 is interposed between the barrier 63 and one of the corresponding second portions 55.

The barrier 63 presents a thickness between 0.5 nm and 10 nm.

The barrier 63 is suitable for being traversed, by tunneling effect or by electrical conduction, by Cooper pairs. However, the barrier 63 is not made of a superconducting material.

For example, the barrier 63 is made of copper.

Each layer 125 is made of a magnetic material.

In particular, the term “magnetic material” will be used for a ferromagnetic material or a ferrimagnetic material.

In a ferromagnetic material, the magnetic moments are oriented parallel to each other. When a ferromagnetic material is subjected to an external magnetic field, the magnetic moments of the material orient themselves, while remaining parallel to each other, in the direction of the external magnetic field.

In a ferrimagnetic material, the magnetic moments are oriented antiparallel to each other, without being perfectly compensated.

The resultant of the moments in a ferrimagnetic material is strictly lower than the resultant of the moments in the same material, if it were ferromagnetic. When a ferrimagnetic material is subjected to an external magnetic field, the magnetic moments of the material orient themselves, while remaining antiparallel to each other, so that the resultant is oriented in the direction of the external magnetic field.

Examples of magnetic materials are nickel Ni and permalloy NiFe.

Each layer 125 is, for example, perpendicular to the direction Y.

Each magnetic layer 125 presents a thickness, measured according to the second direction Y of between 0.5 nm and 2.5 nm.

The control element 40 is able to modify, in a known manner, the magnetization direction of at least one of the magnetic layers 125. For example, the magnetization direction of one of the magnetic layers 125 is fixed while the magnetization direction of the other magnetic layer 125 is movable.

Each magnetization direction is, for example, perpendicular to the second direction Y.

For example, the control element 40 comprises at least one configuration electrode 130, for example two configuration electrodes 130. The control element 40 is configured to generate an electric current flowing through the configuration electrode, one of the magnetic layers 125, the barrier 63, and the other magnetic layer 125. For example, the electric current flows through one of the configuration electrodes 130, part of a second portion 55, one magnetic layer 125, the barrier 63, the other magnetic layer 125, part of the other second portion 55 forming the junction 35 and the other configuration electrode 130.

Through a so-called “spin transfer” effect, the variable direction of magnetization of one of the magnetic layers 125 rotates about an axis parallel to the second direction Y. Thus, the variable direction of magnetization is changed. In particular, an angle between the magnetization directions of the two magnetic layers 125 is changed. Thus, the control element 40 is able to change an angle between the magnetization directions by generating an electric current.

When a current flows through the junction 35, in particular a current flowing between the two end conductors 30A, the electrons flowing through the magnetic layers 125 are subject to a magnetic force that acts on the Cooper pairs. In particular, the phase shift of the Cooper pairs depends on the angle between the magnetization directions. The critical current of the junction 35 is a function (in particular sinusoidal) of this phase shift.

Thus, the critical current of the junction 35 depends on the angle between the magnetization directions of the two magnetic layers 125. When the magnetization directions of the two layers 125 are identical, the critical current of the junction 35 presents a value strictly lower than the value of the same magnitude when the magnetization directions are opposite.

Thus, when the magnetization directions of the two layers 125 are opposite, the junction 35 forms a Josephson junction, whereas the junction 35 does not exhibit the Josephson effect when the magnetization directions are opposite.

A fourth example of barrier 35 and control element 40 will now be described.

The barrier 63 comprises a portion made of a cuprate superconductor material.

The control element 40 includes a configuration electrode in contact with the barrier 63.

The configuration electrode is made of an electronegative metallic material, for example MoSi.

The control element 40 is able to control an electrical potential of the configuration electrode.

The configuration electrode, being electronegative, generates oxygen vacancies in the barrier 63. An oxygen vacancy is a location in the crystal lattice of the barrier 63 that should be occupied by an oxygen atom but is unoccupied because oxygen atoms are attracted to the electrode, a part of which is oxidized by those atoms.

The critical temperature of the cuprates is a function of the amount of oxygen they contain. In particular, the higher the amount of oxygen vacancies, the lower the critical temperature of junction 35. Thus, the critical temperature Tc of the barrier 63 depends on the electrical potential of the configuration electrode. The junction 35 then switches between its two configurations according to whether the electrical potential corresponds to a critical temperature Tc higher or lower than the temperature at which the junction 35 is located.

The invention corresponds to the combination of each of the examples and embodiments presented above.

1. A device including a substrate, a set of electrical conductors carried by a face of the substrate, a set of junctions carried by said face of the substrate and a set of control elements,
each electrical conductor being made of a superconducting material, each electrical conductor comprising a single first portion extending in a first direction tangential to the substrate and a set of second portions, the first portions of the electrical conductors being successively offset relative to each other according to a second direction perpendicular to the first direction,
at least three junctions being interposed according to the second direction between each pair of successive first portions, each junction being connected to the first portion of each of the conductors between which the junction is interposed by a second portion of said conductor,
each control element being associated with a single junction of the set of junctions, and being configured to switch the associated junction between a first configuration in which the junction forms a Josephson junction between the conductors to which the junction is connected and a second configuration in which the junction prevents the passage of Cooper pairs between said conductors.

2. The device according to claim 1, including at least ten electrical conductors, at least ten junctions being interposed between each pair of successive first portions.

3. The device according to claim 1, wherein each second portion extends according to the second direction.

4. The device according to claim 1, wherein each junction includes a barrier forming a barrier between the two second portions connected to the junction, at least one of the following properties being verified:
the barrier is made of a ferroelectric material presenting an electrical polarization, the control element being configured to modify a direction of the electrical polarization;
the barrier is made of an electrically insulating material, the junction further including an electrically conductive layer presenting a first face in contact with the two second portions and a second face opposite the first face, the control element including an electrically insulating barrier layer in contact with the second face and a configuration electrode the barrier layer being interposed between the electrically conductive layer and the configuration electrode, the control element being configured to modify an electrical potential of the configuration electrode,
the junction includes at least two magnetic layers, each magnetic layer being made of a magnetic material, the junction being configured to have an electric current flowing through the barrier and the two magnetic layers, the control element being configured to modify an orientation of a magnetization of at least one of the magnetic layers.

5. The device according to claim 1, further including an output electrode, an input electrode, a power supply, and a sensor, the power supply being able to inject an electric current into the input electrode and to set a magnitude of the electric current at a predetermined value, the electric current flowing through each of the conductors from the input electrode to the output electrode, the sensor being able to measure an electric potential difference between the input electrode and the output electrode.

6. The device according to claim 1, wherein each first or second portion is straight.

7. The device according to claim 1, wherein:
a distance, measured according to the second direction between the two first portions of a pair of successive conductors, is identical for each pair of successive conductors, and/or
a distance, measured according to the first direction between two successive second portions of a same electrical conductor, is identical for each pair of successive second portions.

8. A system including a control module and a device according to claim 1.

9. The system according to claim 8, wherein the control module is configured for:
determining a closed contour on the face of the substrate carrying the conductors and the junctions, the closed contour delimiting a first zone of said face,
controlling a switching of each junction included in the first zone to the corresponding first configuration and a switching of each junction located outside the first zone to the corresponding second configuration
rotating the closed contour through a predetermined angle about an axis perpendicular to the face of the substrate carrying the conductors and the junctions, the closed contour delimiting a second zone upon completion of the rotating, and
controlling a switching of each junction included in the second zone to the corresponding first configuration and a switching of each junction located outside the second zone to the corresponding second configuration.

10. A method for using a device including a substrate, a set of electrical conductors carried by the substrate, a set of junctions and a set of control elements, each electrical conductor being made of a superconducting material, each electrical conductor comprising a single first portion extending according to a first direction tangential to the substrate and a set of second portions the first portions of the electrical conductors being successively offset relative to each other according to a second direction perpendicular to the first direction, at least three junctions being interposed according to the second direction between each pair of successive first portions, each junction being connected to the first portion of each of the conductors, between which the junction is interposed, by a second portion of said conductor,
the method including a step of switching at least one junction between a first configuration in which the junction forms a Josephson junction between the conductors to which the junction is connected and a second configuration in which the junction prevents the passage of Cooper pairs between said conductors.

11. The method according to claim 10, in which, at the end of the switching step, each junction included in a first zone of the face of the substrate carrying the conductors and the junctions is in the first configuration, the first zone being delimited by a closed contour on said face, each junction arranged outside the first zone being in the second configuration, the method further comprising the following steps:
rotating the closed contour through a predetermined angle about an axis perpendicular to the face of the substrate carrying the conductors and the junctions, the closed contour delimiting a second zone on said face after the rotating step, and
switching each junction within the second zone to the corresponding first configuration and switching each junction outside the second zone to the corresponding second configuration.

12. The device according to claim 4, wherein the electrically conductive layer is made of graphene.

13. The system according to claim 8, wherein the system is an antenna.
